(19) United States
(12) Patent Application Publication
(10) Pub. No.: US 2005/0158981 A1
(43) Pub. Date: Jul. 21, 2005

(54) METHOD OF FABRICATING DISPLAY PANEL

(76) Inventors: Shih-Chang Chang, Hsin-Chu Hsien (TW); Hsiu-Chun Hsieh, Chang-Hua City (TW); Yaw-Ming Tsai, Tai-Chung Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/710,200

(22) Filed: Jun. 25, 2004

(30) Foreign Application Priority Data
Jan. 19, 2004 (TW) 093101413

(51) Int. Cl. H01L 21/00

(52) U.S. Cl. 438/620

(57) ABSTRACT

First, a substrate with at least one thin film transistor is provided. A protection layer and a planarization layer are sequentially formed on the substrate. Then, the planarization layer is patterned and an opening is formed in the planarization above the thin film transistor. An etching process is performed by using the planarization layer as a hard mask to form a first contact hole, which is extending through to the thin film transistor, in the protection layer. Then, the planarization layer surrounding the opening is partially removed to form a second contact hole in the planarization layer above the first contact hole. After that, a transparent conductive layer is formed on the surface of the planarization layer, the second contact hole, the first contact hole, partial contact plug and electrically connected to the thin film transistor via the first contact hole and the second contact hole.

### BACKGROUND OF INVENTION

1. Field of the Invention

The present invention relates to a method of fabricating a display panel, and more particularly, to a method of forming a contact hole in a display panel.

2. Description of the Prior Art

In the current TFT process, an inter-layer dielectric (ILD) layer is interposed between the thin film transistor and the metal conductive lines above the transistors for isolating and protecting the electric devices on the display panel. The ILD layer has a plurality of contact holes so that the metal conductive lines can be electrically connected to with the transistors through the contact holes. Thus, data signals can be transferred to sources/drains of the transistors via the metal conductive lines for controlling the operation of the pixels on the display panel.

Please refer to FIG. 1, which is a cross-sectional diagram of a conventional display panel 10. As shown in FIG. 1, the display panel includes a substrate 12, a driving circuit 14 on the substrate 12, and a dielectric layer 16 covering the driving circuit 14 and the substrate 12. Though for clarity only one thin film transistor is illustrated to represent the driving circuit 14 in FIG. 1, the driving circuit 14 in fact includes a plurality of thin film transistors. In addition, the display panel 10 further includes a planarization layer 18 formed on the dielectric layer 16. A contact hole 22 is disposed in the planarization layer 18 so a conductive layer 24 on the planarization layer can be electrically connected to the driving circuit 14 on the substrate 12 through the contact hole 22.

Normally, the planarization layer 18 is composed of polymer materials, such as a photoresist layer. Thus, the contact hole 22 can be formed by an exposure process. The planarization layer 18 is used to planarize the surface of the display panel 10 for fabricating the display unit more easily. Though this structure has an advantage of a simple fabricating process, it also has a problem of high parasitic capacitances and a low protective ability for the driving circuit 14 below. Thus, some methods are developed to solve this problem, such as adding protection layer between the dielectric layer 16 and the planarization 18 to improve the protective ability.

Please refer to FIG. 2, which is a cross-sectional diagram of another conventional display panel 50. As shown in FIG. 2, the display panel 50 has a structure similar to the display panel 10 mentioned above. The display panel 50 includes a substrate 52, a driving circuit 54, and a dielectric layer 56 covering the substrate 52 and the driving circuit 54. The only difference is that a newly added protection layer 58 is formed on the dielectric layer 56. Then, the planarization layer 62 and the conductive layer 68 are formed in sequence. In contrast with the display panel 10, this structure strengthens the protective ability toward the driving circuit below and reduces the parasitic capacitances. Meanwhile, the fabricating process becomes more complex due to the newly added protection layer 58. In contrast with the display panel 10, the display panel 50 requires an additional photo-etching process to define the first contact hole 64 in the protection layer 58 before performing the aforementioned exposure process to form the second contact hole 66 in the planarization layer 62.

Thus, the conductive layer 68 can be electrically connected to the driving circuit 54 on the substrate 52 through the first contact hole 64 and the second contact hole 64. In other words, although this structure has a significant functional advantage, it also increases the complexity of the fabricating process and the fabrication time for the products. In addition, while the first contact hole 64 and the second contact hole 66 are formed, there is also misalignment problem. Once misalignment occurs, electrical connections may fail and the reliability of the products is deteriorated.

Thus, it is important to develop a new method of fabricating a display panel to solve the aforementioned problem.

### SUMMARY OF INVENTION

It is an objective of the claimed invention to provide a method of fabricating a display panel which can form a contact hole by omitting one lithography process used in the conventional method.

In an embodiment of the claimed invention, a method of fabricating an organic light-emitting display panel is disclosed. First, a substrate with at least one thin film transistor is provided. A protection layer and a planarization layer are sequentially formed on the substrate. Then, the planarization layer is patterned and an opening is formed in the planarization above the thin film transistor. An etching process is performed by using the planarization layer as a hard mask to form a first contact hole, which extends through to the thin film transistor, in the protection layer. Then, parts of the planarization layer surrounding the opening are removed to form a second contact hole in the planarization layer above the first contact hole. After that, a transparent conductive layer is formed on the surface of the planarization layer and electrically connected to the thin film transistor via the first contact hole and the second contact hole.

It is an advantage of the claimed invention that the method of the present invention uses the patterned planarization layer as an etching mask to form a contact hole in the protection layer beneath. Thus, the protective ability of the display panel can be improved and the parasitic capacitance is reduced while one lithography process is omitted. Additionally, the alignment problem caused by multiple lithography processes is also solved.

These and other objectives of the claimed invention will not doubt become obvious to those of ordinary skill in the art after reading the following detailed description of the embodiment, which is illustrated in the various figures and drawings.

### BRIEF DESCRIPTION OF DRAWINGS

FIG. 1 is a cross-section diagram of a conventional display panel.

FIG. 2 is a cross-section diagram of another conventional display panel.

FIG. 3 to FIG. 8 are schematic diagrams of a method of fabricating a display panel according to an embodiment of the present invention.

FIG. 9 is a schematic diagram of an electronic device according to an embodiment of the present invention.

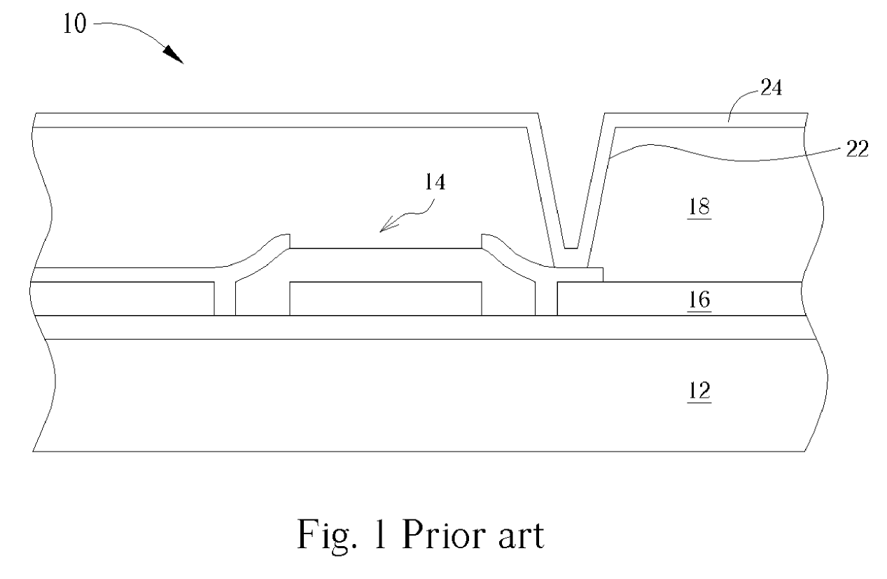

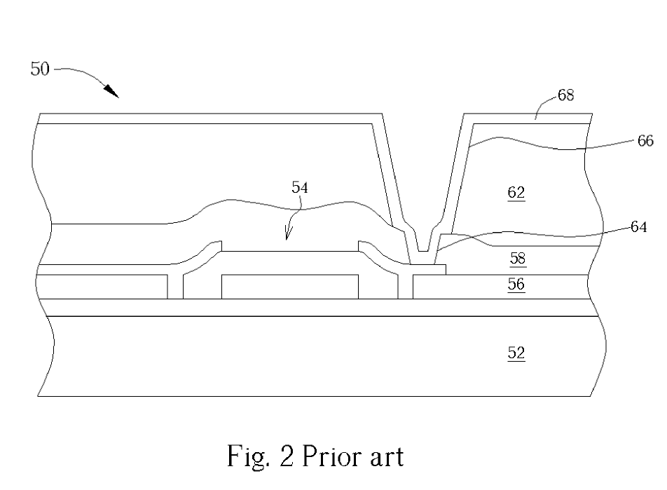

### DETAILED DESCRIPTION

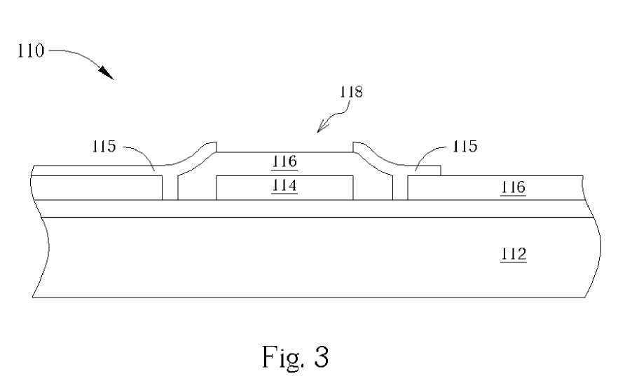

Please refer FIG. 3 to FIG. 8, which are schematic diagrams of a method of fabricating a display panel according to an embodiment of the present invention. As shown in FIG. 3, a display panel 110 includes a substrate 112 with a conductive area. In an embodiment of the present invention, the display panel 110 is an organic light-emitting display panel. A driving circuit 118 and a dielectric layer is formed sequentially on the substrate 112. The conductive area is an exposed part of the driving circuit 118. For clarity, only one thin film transistor is illustrated to represent the driving circuit 118, but the driving circuit 118 has a plurality of thin film transistors electrically connecting with each other for driving the display panel 110 to display images. Each thin film transistor has a gate 114 and a source and a drain located on both side of the gate 114 respectively. The source and drain of each thin film transistor are electrically connected to external devices through a contact plug 115 respectively.

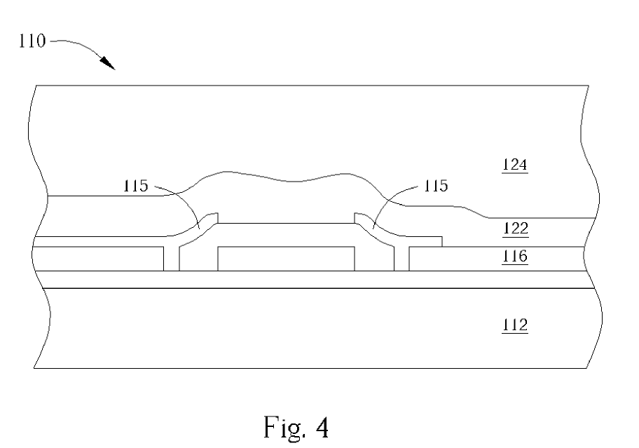

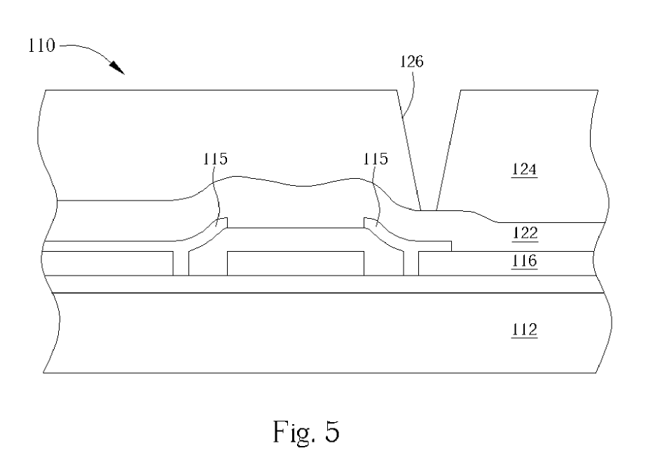

As shown in FIG. 4, a protection layer 122 and a planarization layer 124 are formed on the dielectric layer 116 and the contact plug 115 in sequence. In the present embodiment, the protection layer 122 comprises a silicon nitride layer or a silicon oxide layer with a thickness of about 500 to 5000 angstroms for improving the protective ability toward the beneath electric devices. The planarization layer 124 is composed of organic polymer materials with a thickness of about 500 to 50000 angstroms to maintain a planar surface of the display panel 110 that is advanced to following fabricating processes of display units. As shown in FIG. 5, the planarization is then patterned to form an opening 126 on the thin film transistor directly. In an embodiment of the present invention, a lithography process is used to pattern the planarization layer 124 and remove parts of the planarization layer 124 on the contact plug 115 to form the opening 126.

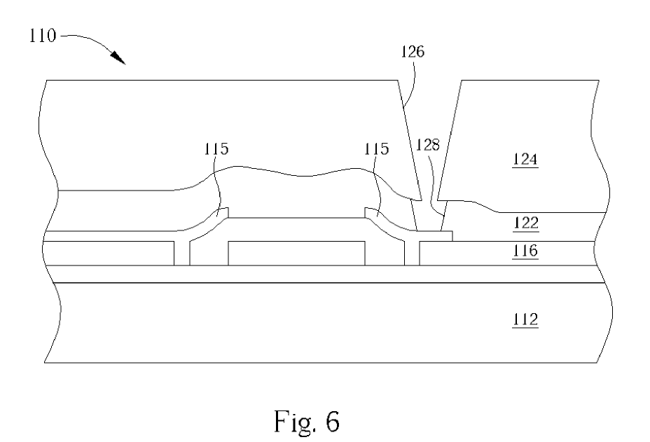

As shown in FIG. 6, an etching process is performed by using the patterned planarization layer 124 as a mask layer to etch the protection layer along the opening 126 for forming a first contact hole 128 and exposing the conductive area which partial of the contact plug 115. It is noted that an undercut phenomenon is occurred and used to enlarge the size of the first contact hole 128. As shown in FIG. 6, the top of the first contact hole 128 has a larger average diameter than that of the bottom of the first contact hole 128. It can significantly improve a reliability of the following electrical connection.

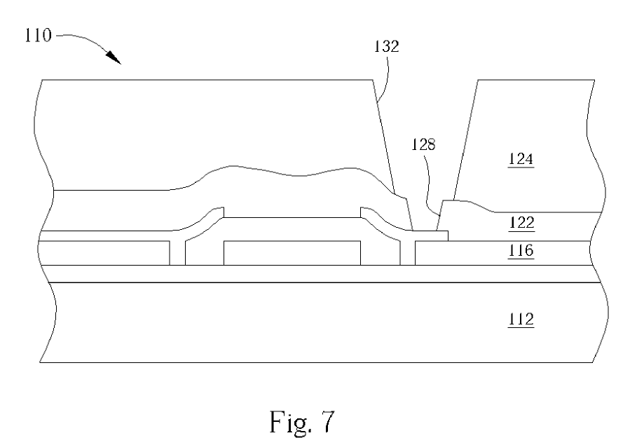

As shown in FIG. 7, parts of the planarization layer 124 surrounding each opening 126 are partially removed to enlarge each opening 126 and form a second contact hole 132 on each first contact hole 128. In an embodiment of the present invention, the method of partially removing parts of the planarization layer 124 can be performed by various processes depending on the materials of the planarization layer 124, such as a descum process or an etching process.

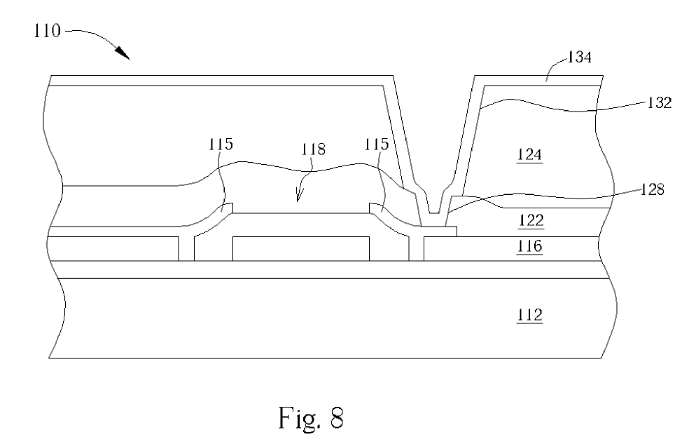

As shown in FIG. 8, a conductive layer 134 is deposited on the surface of the planarization layer 124, the second contact hole 132, the first contact hole 128 and partial contact plug 115. The conductive layer is electrically connected to thin film transistors (the driving circuit 118) beneath through the first contact hole 128 and the second contact hole 132. Then, some display units can be formed on the conductive layer 134 in advance to complete the manufacture of the display panel 110.

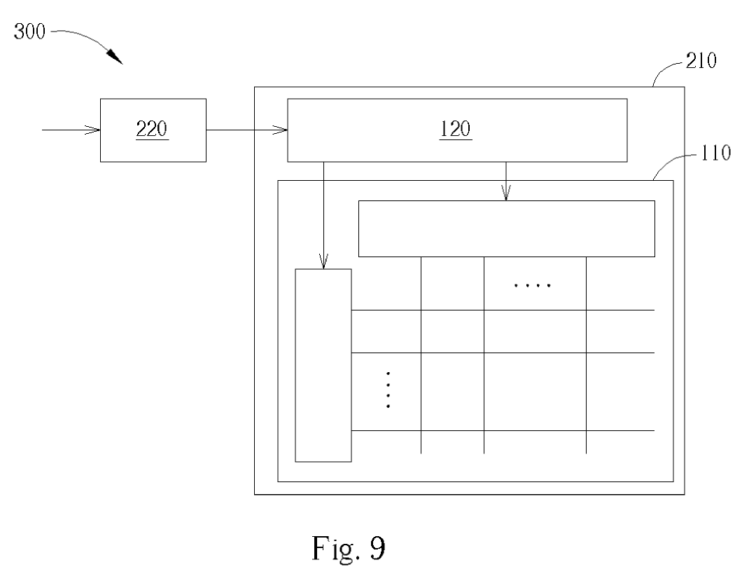

Please refer to FIG. 9, which is a schematic diagram of an electronic device 300 according to the present invention. As shown in FIG. 9, the electronic device 300 includes an input device 220 and a display device 210. The display device 210 further includes a controller 120 and the display panel 110 that is fabricated in accordance with the method mentioned above. The controller 120 coupled to the display panel 110 and the input device 220 coupled to the controller 120 are used to control the display panel 110 to render an image in accordance with an input received from the input device 220. Thus, an electronic device with a display function can be made. Since these fabricating processes should be obvious for one skilled in that art and are not directly related to the present invention, they are not described in detail thereby.

It is noted that though an organic light emitting display panel is illustrated in the aforementioned embodiment, the method of the present invention is not limited to this, and can be applied to other kinds of display panels such as a liquid crystal display panel, or any electronic device with the aforementioned display panel. In addition, the method of the present invention can be applied to a contact hole formation of each kind of TFT display panel, such as active matrix display panel or passive matrix display panel.

In contrast with the prior art, the method of the present invention uses a patterned planarization layer as a mask layer to etch the protection layer beneath and form the contact hole in the protection layer. Thus, one lithography process can be omitted to simplify the fabricating process, improving the protective ability of the display panel, and reducing the parasitic capacitances. In addition, since the first contact hole and the second contact hole are aligned automatically, the misalignment problem caused by multiple lithography processes can be avoided. Therefore, the reliability of the display panel can be improved effectively.

Those skilled in the art will readily observe that numerous modifications and alterations of the invention may be made while retaining the teachings of the invention. Accordingly, the above disclosure should be construed as limited only by the metes and bounds of appended claims.

1. A method of fabricating a display panel, the method comprising the steps of:
providing a substrate having a thin film transistor on the surface of the substrate;
forming a protection layer on the substrate;
forming a planarization layer on the protection layer;
patterning the planarization layer to form an opening;
performing an etching process by using the planarization layer as a mask to form a first contact hole in the protection layer extending through to the thin film transistor; and
partially removing the planarization layer surrounding each opening to enlarge the opening and form a second contact hole.

2. The method of claim 1 wherein the planarization layer comprises a photoresist layer.

3. The method of claim 1 wherein an exposure process and a development process are used to pattern the planarization layer.

4. The method of claim 1 wherein a descum process is used to selectively remove parts of the planarization layer surrounding the openings.

5. The method of claim 1 wherein the protection layer comprises a silicon nitride layer or a silicon oxide layer.

6. The method of claim 1 further comprising depositing a conductive layer on the planarization layer, covering the first contact hole and the second contact hole and electrically connecting to the thin film transistor.

7. The method of claim 6 wherein the conductive layer comprises indium tin oxide (ITO) or indium zinc oxide IZO.

8. The method of claim 1 wherein the display panel is an organic light-emitting display panel or a liquid crystal display panel.

9. A method of fabricating a display panel, comprising the steps of:
providing a substrate with a conductive area on the substrate;
forming a protection layer over the substrate;
forming a patterned photoresist layer with an opening formed on the conductive area;
performing an etching process by using the photoresist layer as a mask to form a first contact hole in the protection layer extending through to the conductive area;
partially removing the photoresist layer surrounding the opening to enlarge the opening and form a second contact hole next to the first contact hole; and
forming a conductive layer on the surface of the photoresist layer electrically connected to the conductive area through the first contact hole and the second contact hole.

10. The method of claim 9 wherein the method of forming the patterned photoresist layer comprises:
forming a photoresist layer on the protection layer;
performing a exposure process to define patterns of the photoresist layer; and
performing a development process to form the opening in the photoresist layer.

11. The method of claim 9 wherein the method uses a descum process to partially remove the photoresist layer surrounding the opening.

12. The method of claim 9 wherein the protection layer comprises a silicon oxide layer or a silicon nitride layer.

13. The method of claim 9 wherein the display panel is an organic light-emitting display panel or a liquid crystal display panel.

14. A display panel fabricated in accordance with the method of claim 9.

15. A display device comprising:
a display panel of claim 14; and
a controller coupled to the display panel to control the display panel to render an image in accordance with an input.

16. An electronic device comprising:
a display device of claim 15; and
an input device coupled to the controller of the display to render an image.
